(19) United States
(12) Patent Application Publication
(10) Pub. No.: US 2018/0274090 A1
(43) Pub. Date: Sep. 27, 2018

(54) METHOD AND APPARATUS FOR COATING INNER SURFACE

(71) Applicant: YAMAGATA UNIVERSITY, Yamagata-shi, Yamagata (JP)

(72) Inventor: Fumihiko HIROSE, Yonezawa-shi, Yamagata (JP)

(21) Appl. No.: 15/765,177

(22) PCT Filed: Oct. 3, 2016
(86) PCT No.: PCT/JP2016/079289

§ 371 Date: Mar. 30, 2018

(30) Foreign Application Priority Data
Oct. 2, 2015 (JP) 2015-197159

(51) Int. Cl. C23C 16/40; C23C 16/455; C23C 16/56; C23C 26/00; H01L 21/205

(52) U.S. Cl. CPC C23C 16/403; C23C 16/401; H01L 21/205; C23C 16/56; C23C 26/00; C23C 16/45527

(57) ABSTRACT

A coating method of an oxide film on an inner surface of an object such as a container or a pipe-shaped object includes steps of connecting a joint part to a connection tube to which an object is to be connected, and bringing an inside of the object into a sealed state, executing introduction of the organometallic gas into the object, evacuating the organometallic gas, introducing the excited humidified gas into the object, and evacuating the humidified gas in the object the evacuating means; and includes repeating the steps to form the oxide film on the inner surface of the object. A coating apparatus is provided with a connecting device for evacuating the object to the joint part, a device for introducing an organometallic gas into the object to fill with the organometallic gas, and a device for introducing an excited humidified gas into the object.

### TECHNICAL FIELD

The present invention relates to an inner surface coating method and an inner surface coating apparatus for applying a coating of a metal oxide film such as silica, alumina, titania on the inner surface of a vacuum chamber or a metal pipe to provide an effect of corrosion resistance.

### BACKGROUND ART

Vacuum chambers are widely used as chemical vapor deposition (CVD) and chemical treatment containers using gas phase chemical reaction. In recent years, production of silicon solar cells, especially amorphous silicon solar cells, has been performed due to the growing demand for renewable energy, and plasma CVD is used to produce amorphous silicon films. In addition, a transparent conductive film forming the amorphous silicon solar cell is formed by CVD. Further, in production of a liquid crystal display, being light and thin, and has widely penetrated in place of a cathode-ray tube display, glass is used as a base material of the panel, and a high-purity glass or oxide coating is applied to the glass plate by using plasma CVD. As represented by the above application, in CVD and plasma CVD, a vacuum chamber is used for storing an object to be treated and forming an atmosphere with a predetermined gas. The vacuum chamber requires characteristics that it is durable against corrosion and is hard to get deposits adhered.

In the above application, consequently deposits originated in reaction products are often adhered to the vacuum chamber. When corrosive gases, such as a halogenated gas like a chlorine gas, are used to flow for removal of the deposits for cleaning, there occurs deposition of metal chlorides and hydrates if metal corrosion is present, which causes degradation of the evacuation characteristics and introduction of impurity contamination to the object to be treated. To prevent the above degradation, machine cleaning as periodic cleaning of the vacuum chamber is manually performed; however, labor costs for cleaning are required, and reduction in production efficiency due to pause of the apparatus is a problem. To solve this problem, it is necessary to form a vacuum chamber to be resistant to corrosion, and to make an inner surface hard to deposit deposits.

To provide an anticorrosion function to the inner wall of a metal tube such as a vacuum chamber, the inner wall is coated with a metal oxide film such as silica, alumina, and zirconia. As a conventional method, thermal spraying is used in which a metal as a material is heated and sprayed to an object in a state close to a melt. With this method, a ceramic film can be layered on a metal part or plate at a relatively high speed, and it is possible to provide anti-corrosion and anti-wear characteristics to the surface. The method, however, is based on the principle of spraying a high-temperature gas jet, and there is a circumstance where it is difficult to uniformly apply the coating on the inner surface of a container having a complicated surface shape or the inner surface of a structure having a narrow flat space. Further, there is also a circumstance where the high-temperature gas jet is sprayed, so that the temperature of the object rises, and it is difficult to apply the coating to a vacuum chamber that contains a fine precision structure vulnerable to thermal distortion due to high temperature. In addition, the method is suitable for applying the coating of a thick film having a thickness of 0.1 mm to 1 mm. However, when the coating is applied to a container having a fine structure such as a flange, a problem arises where dimensional error due to the above film thickness may occur after applying the coating.

In a CVD or chemical treatment apparatus using a corrosive gas such as hydrogen chloride, adopted is a method of coating the inner surface with a metal oxide film such as alumina. As one of commonly used methods, as disclosed in Patent Literature 1, aluminum is used for the vacuum chamber, and the surface thereof is anodized to apply alumite treatment. According to this method, the vacuum chamber is covered with corrosion resistant alumina, and corrosion resistance performance is improved. However, to apply this method, the material of the container is limited to aluminum, and the vacuum chamber itself becomes expensive as compared to a vacuum chamber made of stainless steel, iron, or the like. In addition, aluminum is easily eroded by a material such as gallium, and cannot be applied to a CVD apparatus for compound semiconductors such as a gallium-based thin film, for example, GaN that is a big demand for a blue LED in recent years, so that it has been problematic that the application is limited.

As the method for coating the inner surface of a vacuum chamber or a metal pipe with a metal oxide film, surface treatment is performed using CVD, for example, in which an object to be treated is placed in a vacuum chamber or a furnace. As the metal oxide film, alumina, titania, silica, or the like is used. In the method, as raw material gases, organometallic gases are used: trimethylaluminum for alumina; titanium tetraisopropoxide and tetrakis(dimethylamino)titanium for titania; and tri(dimethylamino)silane for silica. A metal oxide coating is formed by introducing an oxidizing gas such as oxygen in the chamber together with the organometallic gas and heating at a temperature of several hundred degrees Celsius.

However, in this method, a huge vacuum chamber is required that contains a member as an object, and it is problematic that cost of treatment apparatus becomes high. A heating apparatus is also required for heating the inside of the chamber to several hundred degrees Celsius, which causes to increase in apparatus cost. Further, it is also a problematic that energy cost for treatment increases. In addition, since vacuum chambers have various shapes and sizes in accordance with applications, and it is economically difficult to have many surface coating CVD apparatuses according to the variation. In addition, long chambers exceeding several meters used in chemical plants also require inner surface treatment, but it is difficult to build huge CVD apparatus and it is a situation where the inner surface treatment was not possibly applied.

As a method for applying a metal oxide film on the surface of a vacuum chamber or a metal pipe, in addition to CVD, an atomic layer deposition method is also used. For example, in a method for forming an oxide thin film on a substrate in Patent Literature 2, a thin film deposition method is disclosed in which a series of steps are repeated, the series of steps including:

a step of placing a substrate in a reaction chamber, maintaining a temperature of the substrate at higher than 0° C. and equal to or lower than 150° C., preferably equal to or lower than 100° C., and filling a reaction chamber with an organometallic gas such as trimethylaminosilane, bisdimethylaminosilane, and methylethylamino hafnium; a step of evacuating the organometallic gas or filling an inside of the reaction chamber with an inert gas such as a nitrogen gas, argon gas, or helium;
a step of introducing an oxidizing gas whose activity is increased, such as oxygen or water vapor converted into plasma; and
a step of evacuating the oxidizing gas or filling the reaction chamber with the inert gas such as the nitrogen gas, argon gas, or helium.
As an example of this method, a case is introduced in which silica, an inorganic oxide, is formed on an object, a vacuum chamber, at room temperature by placing a solid to be treated in a vacuum chamber in a non-heated state. Also in this method, to coat the inner surface of the vacuum chamber with the metal oxide film, a huge vacuum chamber is required that contains a member as an object, and similar to the above description, there arises a problem where a cost of a treatment apparatus becomes high. Further, for practical use, for vacuum chambers that may have respective various shapes and sizes in accordance with applications, it is necessary to prepare atomic layer deposition apparatuses having respective various reaction chamber sizes corresponding to the vacuum chambers.

### CITATION LIST

### Patent Literature

Patent Literature 1: JP 2003-243372 A

Patent Literature 2: JP 2013-11476 A

### SUMMARY OF INVENTION

### Technical Problem

In view of the above-described circumstances, it is an object of the present invention to provide a method and apparatus for coating the inner surface of a long vacuum chamber or a metal pipe with a metal oxide film such as silica, alumina, titania, or the like, without specially preparing a large apparatus. That is, the CVD or atomic layer deposition method has been conventionally used for the above inner surface treatment, and a huge vacuum chamber and a large heating apparatus have been required; the apparatus cost and energy cost have been high. The present invention, however, aims at applying a coating, at low cost, on the inner surface of the vacuum chamber to be treated or the metal pipe without requiring the huge vacuum chamber.

### Solution to Problem

The present invention to achieve the above object is an inner surface coating method for forming an oxide film on an inner surface of an object to be treated, the object being a container or a pipe-shaped object, the method including: connecting a joint part to a connection tube to which at least one object to be treated is to be connected, to bring an inside of the object to be treated into a sealed state;

connecting, to the joint part, an evacuating means for evacuating gas in the object to be treated, an organometallic gas introducing means that introduces an organometallic gas into the object to be treated and fills the object with the organometallic gas, and a humidified gas introducing means that introduces an excited humidified gas into the object to be treated and fills the object with the humidified gas; and

carrying out

(1) a step of introducing the organometallic gas into the object to be treated by the organometallic gas introducing means,

(2) a step of evacuating the organometallic gas in the object to be treated by the evacuating means,

(3) a step of introducing the excited humidified gas into the object to be treated by the humidified gas introducing means, and

(4) a step of evacuating the humidified gas in the object to be treated by the evacuating means, and repeating the steps (1) to (4), to form the oxide film on the inner surface of the object to be treated.

In the present invention, the object to be treated is a vacuum chamber, and a joint part to which a tube can be connected for merging is connected to one place of the vacuum chamber. Carrying out the steps (1) to (4) enables to form the oxide film on the inner surface of the vacuum chamber without heating the object to be treated. Thus, inner surface coating can be achieved without preparing large vacuum equipment.

To the joint part, further connected is an inert gas introducing means that introduces an inert gas into the object to be treated and fills the object with the inert gas. It is preferable to introduce the inert gas into the object to be treated with the inert gas introducing means in the step (2) and in the step (4).

With this construction, since the organometallic gas is completely substituted with the inert gas in the step (3), a film having excellent quality can be formed when the humidified gas is introduced.

In addition, it is preferable that the humidified gas introducing means introduces excited argon (Ar) or helium (He) that contains water vapor; the excited humidified gas is prepared as follows: Ar or He gas containing water vapor is introduced into a glass tube, then excited using gas plasma generated by a radio frequency magnetic field from around the glass tube.

With this method, the excited humidified gas can be introduced relatively easily.

In addition, it is preferable that, in the step (3), organometallic gas molecules adsorbed on the inner surface of the object to be treated are oxidized and decomposed to form a metal oxide, and a hydroxyl group is formed on a surface of the metal oxide.

With this method, a coating layer can be formed of a metal oxide film having durability.

In addition, it is preferable that a plurality of types of organometallic gases is used, and a plurality of types of films is repeatedly layered sequentially for every one cycle or a plurality of cycles to form a multilayered oxide film.

With this method, the multilayer film can be formed relatively easily.

In addition, it is preferable that an aluminum-based compound and a titanium-based compound are used as the organometallic gas, and alumina and titania are alternately layered.

With this method, a coating with a layered film of alumina and titania can be achieved relatively easily.

Another aspect of the present invention is an inner surface coating apparatus for forming an oxide film on an inner surface of an object to be treated, the object being a container or a pipe-shaped object; the apparatus includes a connection tube to be connected to the object to be treated; and a joint part to be connected to the object to be treated via the connection tube, and the joint part is connected to an evacuating means for evacuating gas in the object to be treated, an organometallic gas introducing means that introduces an organometallic gas into the object to be treated and fills the object with the organometallic gas, and a humidified gas introducing means that introduces an excited humidified gas into the object to be treated and fills the object with the humidified gas.

According to this aspect, it is possible to transport the inner surface coating apparatus to a site on which the object to be treated is placed, and apply the inner surface coating at the site, so that a coating can be formed on the inner surface of a large object to be treated without preparing large vacuum equipment.

Here, it is preferable that the joint part is further connected to an inert gas introducing means that introduces an inert gas into the object to be treated and fills the object with the inert gas.

With this configuration, substitution can be easily performed of the organometallic gas or the humidified gas with the inert gas.

The present invention has been completed on the basis of a finding that a metal oxide coating can be formed on the inner surface of the object to be treated by using atomic layer deposition method, by employing a technique capable of applying a coating without heating the object to be treated; using a vacuum chamber as the object to be treated itself to which the coating is to be applied on the inner surface; connecting the joint part to one place of the object to be treated; and by only connecting, to the joint part, an evacuating means for evacuating gas in the object to be treated, an organometallic gas introducing means that introduces an organometallic gas into the object to be treated and fills the object with the organometallic gas, and a humidified gas introducing means that introduces an excited humidified gas into the object to be treated and fills the object with the humidified gas.

In addition, the inner surface coating apparatus of the present invention includes a connection tube to be connected to the object to be treated and a joint part to be connected to the object to be treated via the connection tube, and the apparatus has a construction which includes an evacuating means for evacuating gas in the object to be treated, an organometallic gas introducing means that introduces an organometallic gas into the object to be treated and fills the object with the organometallic gas, and a humidified gas introducing means that introduces an excited humidified gas into the object to be treated and fills the object with the humidified gas, all of which are connected to the joint part. This construction enables to form a coating on the inner surface by only connecting the apparatus to the object to be treated without heating the object to be treated, so that it is useful to be used for inner surface coating of a large object to be treated. That is, the coating can be formed on the inner surface by only transporting the inner surface coating apparatus to the site where the large object to be treated is placed and connecting, so that the apparatus is very useful.

Note that, here, the range of the large object to be treated is not particularly limited; however, for example, the object is one having a dimension in one direction exceeding 1 m, or a capacity of 50 liters, preferably more than 100 liters, and there is no particular limitation on size and shape.

The present invention has been completed on the basis of a finding that, even in the case of such a large object to be treated, if the large object can be sealed and the connection tube can be connected to one place thereof, by only evacuating the inside and introducing organometallic gas, the inside of the object to be treated is instantaneously filled with the organometallic gas, and the organometallic gas is easily adsorbed to the entire inner surface of the object to be treated, and then, after evacuation, by only introducing the excited humidified gas, the entire inside of the object to be treated is instantaneously filled with the excited humidified gas, and the organometallic gas adsorbed on the inner surface is oxidatively decomposed into a metal oxide, and by only repeating the above, a coating made of a metal oxide film can be easily formed.

### Advantageous Effects of Invention

By using the present invention, it is possible to form a metal oxide film on the inner surface of a vacuum chamber or a metal pipe to provide a function of improving corrosion resistance.

### BRIEF DESCRIPTION OF DRAWINGS

FIG. 1 is a schematic configuration diagram of an apparatus that forms an oxide film on an inner surface of a vacuum chamber according to an embodiment of the present invention.

FIG. 2 is a schematic configuration diagram of an apparatus that forms an oxide film on inner surfaces of a plurality of vacuum chambers according to another embodiment of the present invention.

FIG. 3 is a schematic configuration diagram of an apparatus that forms an oxide film on inner surfaces of a plurality of metal pipes according to another embodiment of the present invention.

FIG. 4 is a schematic configuration diagram of an excited humidified gas generating apparatus according to an embodiment of the present invention.

FIG. 5 is photographs of a flanged fitting tube on the inside of which silica is coated with a thickness of 100 nm, relating to Example 2 of the present invention.

FIG. 6 is a photograph illustrating a test result of Example 3.

FIG. 7 is a photograph illustrating a test result of Example 4.

FIG. 8 is a schematic configuration diagram of an apparatus according to another embodiment of the present invention.

### DESCRIPTION OF EMBODIMENTS

Hereinafter, the present invention will be described on the basis of an embodiment.

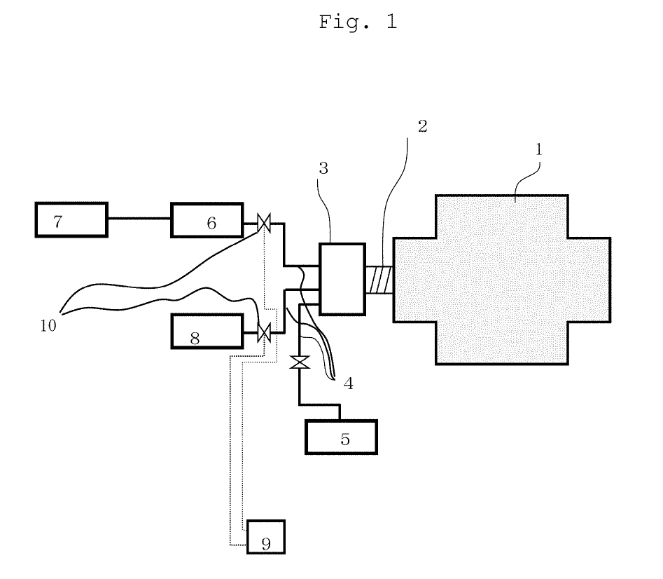

An inner surface coating method according to the present invention is based on the principle of a room temperature atomic layer deposition method capable of film formation at room temperature, and FIG. 1 illustrates an example of an inner surface coating apparatus for carrying out the method.

An inner surface coating apparatus according to an embodiment is connected to a container 1 that is an object to be treated. The inner surface coating apparatus includes a connection tube 2 to be connected to the container 1 made of stainless steel in the present embodiment, and a joint tube 3 that is a joint part connected via the connection tube 2. The joint tube 3 is a small vacuum chamber, and a vacuum pump 5 that is an evacuating means is connected to the joint tube 3 via a pipe 4A. In addition, a flow controller 6 and an organometallic gas container 7 that are organometallic gas introducing means are connected to the joint tube 3 via a pipe 4B. Further, a humidified gas generating apparatus 8, generating an excited humidified gas, (referred to as a humidified gas generating apparatus 8) that is a humidified gas introducing means is connected to the joint tube 3 via a pipe 4C. Note that, valves 9A to 9C are respectively connected to the three pipes 4A to 4C connected to the joint tube 3, and the valves 9A to 9C can be controlled by a valve control apparatus 10.

Here, in the present example, the connection tube 2 is used having an inner diameter of 20 mm to 100 mm and a length of 50 mm.

With this configuration, the inside of each of the container 1 and the joint tube 3 can be brought into a substantial vacuum state using the vacuum pump 5.

In addition, an organometallic gas can be introduced into and fill the container 1 and the joint tube 3 through the flow controller 6 and from the organometallic gas container 7.

Here, as the flow controller 6, for example, a mass flow controller having a maximum flow rate of 100 sccm is used to prevent excessive flow of the organometallic gas into the joint tube 3.

For organometallic gas, for example, tris(dimethylamino)silane for a silica coating, trimethylaluminum for an alumina coating, tetrakis(dimethylamino)titanium for a titania coating are used.

Further, an excited humidified gas can be introduced into and fill the container 1 and the joint tube 3 with the excited humidified gas generating apparatus 8.

FIG. 4 illustrates an example of the excited humidified gas generating apparatus. As shown in FIG. 4, a carrier gas introduction tube 11 is inserted into water in a water bubbler 12, and a glass tube 13 as a discharge tube is connected to the water bubbler 12. An induction coil 14 is provided around the glass tube 13 to generate plasma 15 in the glass tube 13.

Here, argon is used as a carrier gas; however, a rare gas such as helium can be used as a substitute. The carrier gas is introduced through the carrier gas introduction tube 11 and passes through the water in the water bubbler 12 to be humidified. The temperature of the water at in this case is in a range from 25° C. to 60° C. The humidified gas is produced here, and a radio frequency magnetic field is applied using the induction coil 14 to produce the plasma 15 in the glass tube 13, and the excited humidified gas is produced there. Active species of water molecules, for example, OH, monoatomic oxygen, and hydrogen are produced here and can be efficiently introduced into the joint tube 3 with the carrier gas. Note that, a radio frequency current applied to the induction coil 14 is of 13.56 MHz, for example, and a radio frequency power is in a range from 30 W to 50 W, for example.

Hereinafter, a configuration of the present apparatus will be described while explaining the inner surface coating method using the apparatus.

First, using the apparatus, a step is performed of introducing the humidified gas excited by the plasma into the container 1 and filling the container 1 with the humidified gas. Specifically, in order to carry out this step, the valve 9A is opened to evacuate the inside of the container 1 and the joint tube 3 to about 10⁻³ Pa with the vacuum pump 5. Then the valve 9C is opened to introduce the excited humidified gas from the humidified gas generating apparatus 8 into and fill the container 1. As a result, surface contamination of the inner surface of the container 1 is removed, and then a hydroxyl group is formed on the surface of the container 1. The chemical reaction is as follows:

M-O-M+OH+H->2M-OH (M is a metal atom).

The above step is a preliminary step, and if the container 1 is clean and has a hydroxyl group on the surface, it is not necessary to carry out the preliminary step.

Next, the valve 9C is closed and the introduction of the excited humidified gas is stopped, and the valve 4A is opened and the inside of each of the container 1 and the joint tube 3 is evacuated to about 10⁻³ Pa with the vacuum pump 5. After that, the valve 9B is opened and the flow controller 6 is controlled to introduce a predetermined amount of organometallic gas into the container 1 from the organometallic gas container 7.

As a result, the organometallic gas introduced into the container 1 reacts with the hydroxyl group on the inner surface of the container 1 and is adsorbed. At this time, when all the hydroxyl groups are consumed by adsorption, the adsorption autonomously stops, and a layer of gas molecules corresponding to a monomolecular layer is formed on the inner surface. After that, the valve 9B is closed and the introduction of the organometallic gas is stopped, and the valve 9A is opened and a residual gas in the container 1 is evacuated with the vacuum pump 5.

After the inside of each of the container 1 and the joint tube 3 are evacuated to about 10⁻³ Pa, the valve 9C is opened and the excited humidified gas is introduced into the container 1 from the humidified gas generating apparatus 8. As a result, the excited humidified gas fills the inside of each of the joint tube 3 and the container 1. The excited humidified gas oxidizes the gas molecule adsorption layer of the monomolecular layer, and a thin metal oxide coating is formed. Further, a hydroxyl group is formed on the surface of the thin metal oxide coating.

Next, the valve 9C is closed and the introduction of the excited humidified gas is stopped, and the valve 9A is opened and the residual gas in the joint tube 3 and the container 1 connected thereto is evacuated with the vacuum pump 5.

Through the above-described (1) the organometallic gas introduction step, (2) the vacuum evacuation step, (3) the excited humidified gas introduction step, and (4) the vacuum evacuation step, a metal oxide film corresponding to the monomolecular layer is formed on the inner surface of the container 1 at room temperature.

Then, by repeating the above steps (1) to (4), the metal oxide film having a film thickness proportional to the number of repetitions is formed on the inner surface of the container 1.

To carry out the above steps, the valve control apparatus 10 performs opening and closing operation of the valves 9A to 9C to sequentially performs (1) introduction and stop of the organometallic gas, evacuation with the vacuum pump 5, and introduction and stop of the humidified argon gas excited by the plasma. The present apparatus is set, using the valve control apparatus 10, such that two or more of the valves 9A to 9C cannot be opened at the same timing. This is to prevent each gas from flowing backward to the other supply apparatus side.

As the film type of the metal oxide film, silica, alumina, and titania are conceivable; tris(dimethylamino)silane for applying silica, trimethylalumina for alumina, and tetrakis(dimethylamino)titanium for titania are used as the organometallic gas.

As described above, the configuration of the invention illustrated in FIG. 1 assumes that the object to be treated is a vacuum chamber and a single container is treated; however, to treat a plurality of containers at the same time, using a branched connection tube, treatment is possible with one joint tube 3.

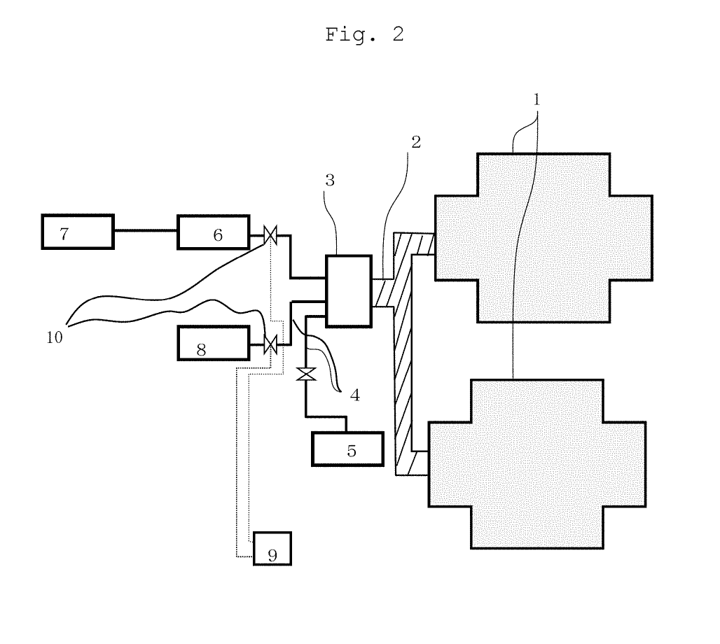

In FIG. 2, one joint tube 3 is connected to two containers 1 using a connection tube 2A branched into two. In this case as well, coating is possible similarly to the case in the first embodiment.

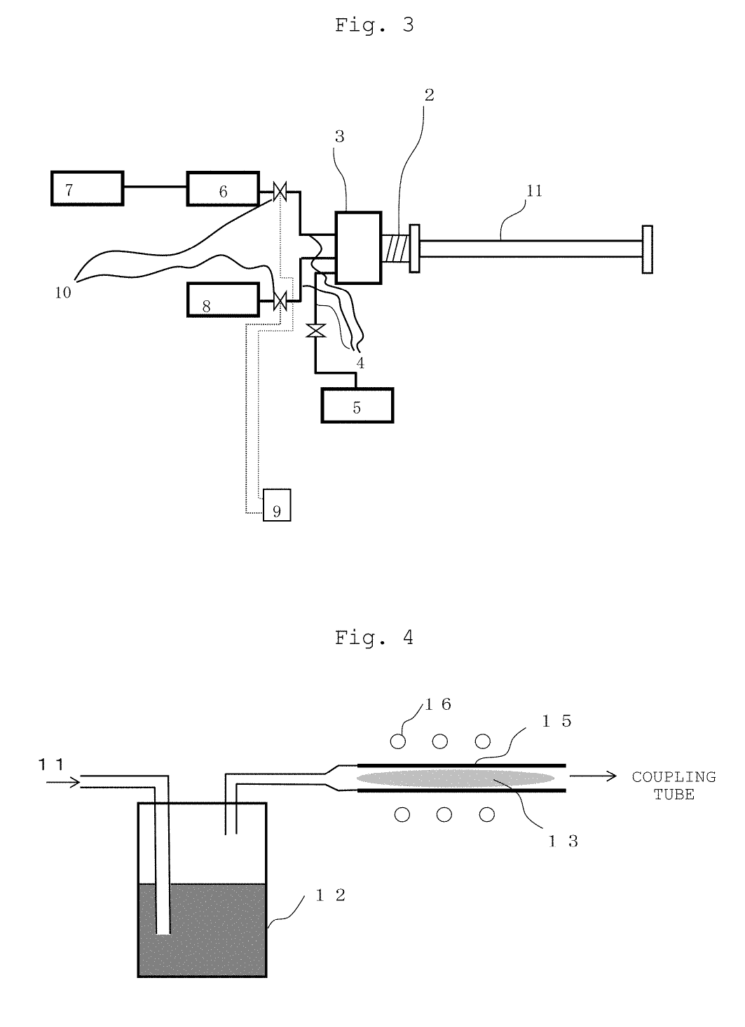

Further, as the object to be treated, it is possible to treat pipes made of various metals and the like, and objects similar to pipes, instead of the vacuum chamber. FIG. 3 illustrates a case where a pipe 1A made of stainless steel is connected to the connection tube 2A. In this case, the opposite side of the pipe 1A is sealed. In this case as well, coating can be performed similarly.

Note that, the container 1 and the pipe 1A are not limited to the illustrated shapes, and coating can be performed without problems even if the container 1 and the pipe 1A have complicated shapes. That is, a container or a pipe having a complicated shape may be used if the container or the pipe can be evacuated with the vacuum pump 5, and the organometallic gas and the excited humidified gas instantaneously reach every corner in every state, and an oxide film can be formed to every corner. In addition, as described above, even if an object has a complicated shape, there is no need to heat the object, so that there is an advantage that coating can be easily performed.

In the present invention, in the coating layer formed on the inner surface of the container 1 or the pipe 1A, it is preferable to layer a plurality of types of metal oxide films in multiple layers, as compared with the case of layering a single layer film. This is probably because when the metal oxide film is layered on a different type of material, distortion tends to occur in the film, and if the film thickness becomes too large, peeling of the film occurs and cracks occur in the film, which may impair corrosion resistance durability performance. For that reason, by setting the thickness of a film to such a level as not to cause cracks, preferably by forming a multilayer lamination of the film with different types of oxide films interposed therebetween, occurrence of distortion is reduced, film peeling hardly occurs, and cracking hardly occurs, which is desirable.

Further, as a result of intensive investigations, it is preferable to use a coating layer mainly composed of an alumina film to improve corrosion resistance performance. Especially on the stainless steel, even if the alumina film is layered more than 30 nm, improvement in corrosion resistance is small, so that the alumina film is preferably layered less than that thickness.

In addition, when it is desired to form an alumina film having a thickness of more than 30 nm, a titania film is layered between alumina films having a thickness of 30 nm or less to form a multilayer structure, whereby more effective corrosion resistance performance can be obtained than that in an alumina single layer film having the same film thickness. The titania film here may be very thin as compared with the alumina film as the main material, and may be about 1 nm to 15 nm, for example. In a case where silica, hafnia, zirconia, and the like are sandwiched instead of titania, a similar effect is achieved.

### Example 1

A silica coating was applied to the inner surface of a cylindrical vacuum chamber having an inner diameter of 200 mm and a length of 200 mm. ICF 253 flanges were attached to the two end surfaces of the cylinder of the vacuum chamber and an ICF 103 flange was attached to the side surface. The ICF 253 flange was covered with a blank flange, and the ICF 103 flange was connected to the connection tube 2 illustrated in FIG. 1 having an inner diameter of 70 mm. To confirm whether the inner surface of the vacuum chamber was uniformly coated, eight test pieces of Si samples were pasted to the side surfaces near the both ends of the ICF 253 flange, and the thicknesses of the silica films layered on the test pieces of Si samples were measured.

As for the film formation procedure, the excited humidified argon gas was first introduced into the vacuum chamber to be treated. The duration time of introduction then was 2 minutes. As for the generation method of the activated humidified argon gas, the apparatus illustrated in FIG. 4 was used, argon gas was controlled to flow at a flow rate of 10 sccm into the water bubbler 12, and the temperature of the water of the water bubbler 12 was set to 60° C., and subsequently the humidified argon gas was produced in the glass tube 13 in which the plasma 15 was generated by using the induction coil 14. The high frequency power introduced through the induction coil 14 was 30 W. After introducing the excited humidified gas into the vacuum chamber, the vacuum chamber was evacuated performed with the vacuum pump 5, and then trimethylaminosilane was introduced at 2.3 sccm for 20 seconds. Then, the inside of the vacuum chamber was evacuated with the vacuum pump 5. These series of steps were referred to as an ALD cycle, and the ALD cycle was performed 70 times to coat the inner surface of the vacuum chamber with the silica film together with the small piece samples of silicon. The film thickness of the coated silica was measured by spectroscopic ellipsometry.

The measurement results are shown in Table 1 below.

TABLE 1

| | |
|---|---|
| Top row arrangement | Lower row arrangement |

| Test piece | Silica film | Test piece | Silica film |
|---|---|---|---|
| number | thickness (nm) | number | thickness (nm) |
| 1 | 4.91 | 5 | 5.16 |
| 2 | 4.94 | 6 | 5.11 |
| 3 | 4.63 | 7 | 4.95 |
| 4 | 4.79 | 8 | 4.96 |

As shown in Table 1, the film thicknesses of the silica of the Si samples as the test pieces were obtained in a range from 4.63 nm to 5.16 nm, the average was 4.93 nm, the variation was 3.4%, and it is found that the silica coating was sufficiently uniformly made inside the vacuum chamber.

### Example 2

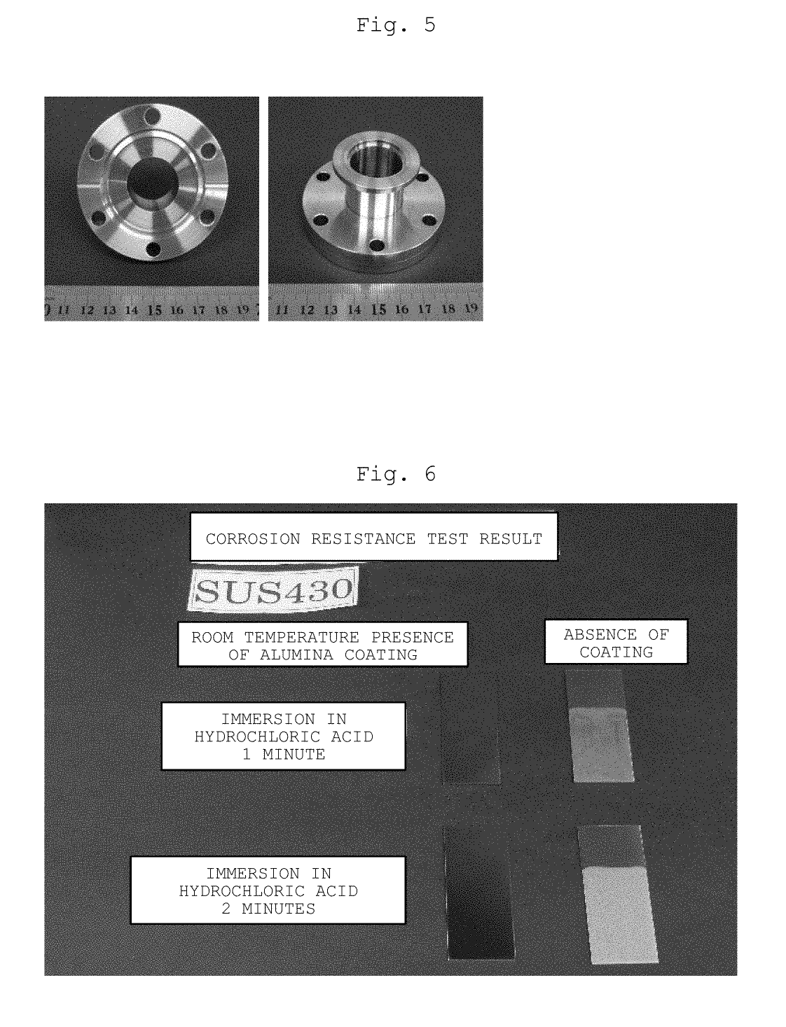

FIG. 5 illustrates an example in which an ICF 70-NW 25 conversion flange made of stainless steel was regarded as a metal pipe and its inner surface was coated with silica. Conditions for film formation were the same as those in Example 1, and in this case, the number of cycles was 1400 times, and the thickness of the silica was 100 nm. The inner surface looks blue due to an interference color and any part of the inner surface has the same color. Therefore, it is found that the silica is a uniform film by interference color determination.

### Example 3

A test was conducted of applying an alumina coating of a thickness of 30 nm on the inner surface of a vacuum chamber having an inner diameter of 120 mm and a length of 200 mm. In this case, a sample plate of stainless steel SUS430 was pasted to the inner surface of the vacuum chamber, and the sample was used to evaluate the effect of corrosion resistance performance of the surface coating. FIG. 6 illustrates the result of evaluating the change of the surface state by immersing the sample in concentrated hydrochloric acid at 25° C.

It is shown that in the absence of the alumina coating corrosion marks were easily formed in about 1 minute, but in the presence of the alumina coating, durability against concentrated hydrochloric acid was more than 2 minutes. It is found that the corrosion resistant coating was formed on the inner surface of the vacuum chamber with the present technique.

### Example 4

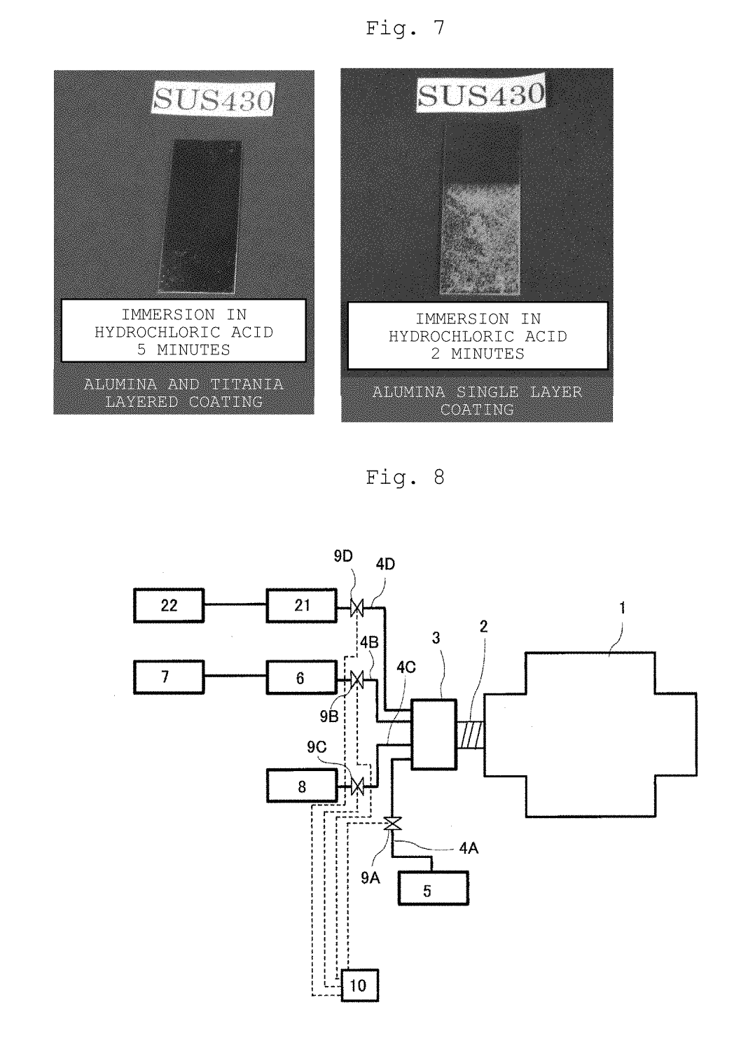

A test of applying an alumina single layer coating on the inner surface of a vacuum chamber having an inner diameter of 120 mm and a length of 200 mm, and a test of alternately layering alumina and titania films, were conducted. In this case, to form alumina, trimethylaluminum as organometallic gas, and tetrakis(dimethylamino)titanium for forming titania were used. As for the order of layering, alumina was first layered on the inner wall with a film thickness of 7.5 nm, and then titania was layered with 3.9 nm, and the alumina and titania films as one set were layered four sets, and a total of 45.7 nm coating was carried out. As a reference, a test was conducted of applying an alumina coating of approximately the same film thickness. In this case, a sample plate of stainless steel SUS430 was pasted to the inner surface of the vacuum chamber, and the sample was used to evaluate the effectiveness of corrosion resistance performance of the surface coating. FIG. 7 shows the result of evaluating the change of the surface state by immersing the sample in concentrated hydrochloric acid at 25° C.

It is found that noticeable corrosion marks on the surface were not observed up to 5 minutes in the case of the multilayer coating, whereas corrosion marks appeared in about 3 minutes in the single layer coating. It is found that in a case where the inner wall of the vacuum chamber was coated with an oxide film, the resistance to corrosion was higher in the multilayer case in which plural types of films were repeatedly layered than in the single layer coating.

### Other Embodiments

In the above-described embodiments and examples, the metal oxide film corresponding to the monomolecular layer is formed at room temperature by the steps of (1) the organometallic gas introduction step, (2) the vacuum evacuation step, (3) the excited humidified gas introduction step, and (4) the vacuum evacuation step; however, an inert gas may be introduced into the object to be treated by the inert gas introducing means, in the step (2), and the inert gas may be introduced into the object to be treated by the inert gas introducing means, in the step (4). As a result, the substitution of the organometallic gas with the excited humidified gas can be performed more completely, so that a metal oxide film with further excellent film quality is formed.

FIG. 8 illustrates an example of an apparatus including such an inert gas introducing means. The apparatus shown in FIG. 8 is the same as the apparatus shown in FIG. 1 except that the inert gas introducing means is added to the apparatus described in the first embodiment, so that duplicate explanation will be omitted.

In the apparatus shown in FIG. 8, a flow controller 21 and an inert gas container 22 as inert gas introducing means are connected to the joint tube 3 via a pipe 4D, and a valve 9D is interposed between the pipe 4D and the inert gas introducing means. The valve 9D can be controlled by the valve control apparatus 10. Note that, the inert gas container 22 is filled with an inert gas such as argon, helium, or nitrogen.

To carry out the above steps in the apparatus, the valve control apparatus 10 performs opening and closing operation of the valves 9A to 9D in order to sequentially perform (1) introduction and stop of the organometallic gas, evacuation by the vacuum pump 5, introduction and stop of the inert gas, evacuation by the vacuum pump 5, introduction and stop of the humidified argon gas excited by the plasma, evacuation by the vacuum pump 5, introduction and stop of the inert gas, and evacuation by the vacuum pump 5. The present apparatus is set such that two or more of the valves 9A to 9C are not opened at the same timing, by the valve control apparatus 10. This is to prevent each gas from flowing backward to the other supply apparatus side.

### INDUSTRIAL APPLICABILITY

As an example of the application field, the present invention can be used for anticorrosion coating and surface modification of the inner surface of vacuum chambers for chemical vapor deposition and chemical reaction treatment.

### REFERENCE SIGNS LIST

1 Vacuum chamber to be treated
2 Connection tube
3 Connection tube
4A to 4D Pipe
5 Vacuum pump
6 Flow controller
7 Organometallic gas container
8 Excited humidified gas generating apparatus
9A to 9D valve
10 Valve control apparatus
11 Carrier gas introduction tube
12 Water bubbler
13 Glass tube
14 Induction coil
21 Flow controller
22 Inert gas container

What is claimed is:

1. An inner surface coating method for forming an oxide film on an inner surface of an object to be treated, the object being a container or a pipe-shaped object, the method comprising:
connecting a joint part to a connection tube to which at least one object to be treated is to be connected, for bringing an inside of the object to be treated into a sealed state;
connecting, to the joint part, an evacuating means for evacuating gas in the object to be treated, an organometallic gas introducing means that introduces an organometallic gas into the object to be treated and fills the object with the organometallic gas, and a humidified gas introducing means that introduces an excited humidified gas into the object to be treated and fills the object with the humidified gas; and
executing
(1) a step of introducing the organometallic gas into the object to be treated by the organometallic gas introducing means,
(2) a step of evacuating the organometallic gas in the object to be treated by the evacuating means,
(3) a step of introducing the excited humidified gas into the object to be treated by the humidified gas introducing means, and
(4) a step of evacuating the humidified gas in the object to be treated by the evacuating means, and
repeating the steps (1) to (4), to form the oxide film on the inner surface of the object to be treated.

2. The inner surface coating method according to claim 1, comprising:
further connecting, to the joint part, an inert gas introducing means that introduces an inert gas into the object to be treated and fills the object with the inert gas;
introducing the inert gas into the object to be treated with the inert gas introducing means, in the step (2); and
introducing the inert gas into the object to be treated with the inert gas introducing means, in the step (4).

3. The inner surface coating method according to claim 1, wherein
the humidified gas introducing means introduces argon or helium containing water vapor into a glass tube, applies a radio frequency electromagnetic field from around the glass tube, generates plasma inside the glass tube to generate a humidified gas excited by the plasma, and introduces the excited humidified gas.

4. The inner surface coating method according to claim 1, wherein
in the step (3), organometallic gas molecules adsorbed on the inner surface of the object to be treated are oxidized and decomposed to form a metal oxide, and a hydroxyl group is formed on a surface of the metal oxide.

5. The inner surface coating method according to claim 1, wherein
a plurality of kinds of organometallic gases is used, and a plurality of kinds of films is repeatedly layered sequentially for every one cycle or a plurality of cycles to form a multilayer oxide film.

6. The inner surface coating method according to claim 5, wherein
an aluminum-based compound and a titanium-based compound are used as the organometallic gas, and alumina and titania are alternately layered.

7. An inner surface coating apparatus for forming an oxide film on an inner surface of an object to be treated, the object being a container or a pipe-shaped object, the apparatus comprising:
a connection tube to be connected to the object to be treated; and
a joint part to be connected to the object to be treated via the connection tube, wherein
the joint part is connected to an evacuating means for evacuating gas in the object to be treated, an organometallic gas introducing means that introduces an organometallic gas into the object to be treated and fills the object with the organometallic gas, and a humidified gas introducing means that introduces an excited humidified gas into the object to be treated and fills the object with the humidified gas.

8. The inner surface coating apparatus according to claim 7, wherein
the joint part is further connected to an inert gas introducing means that introduces an inert gas into the object to be treated and fills the object with the inert gas.
